(19) United States
(12) Patent Application Publication
(10) Pub. No.: US 2026/0344380 A1
(43) Pub. Date: Oct. 29, 2026

(54) CRYSTAL, LAMINATED STRUCTURE, ELEMENT, ELECTRONIC DEVICE, ELECTRONIC APPARATUS, AND SYSTEM

(71) Applicant: Gaianixx Inc., Tokyo (JP)

(72) Inventor: Takeshi Kijima, Tokyo (JP)

(73) Assignee: Gaianixx Inc., Tokyo (JP)

(21) Appl. No.: 19/107,106

(22) PCT Filed: Aug. 31, 2023
(86) PCT No.: PCT/JP2023/032023

§ 371 Date: Feb. 27, 2025

(30) Foreign Application Priority Data
Aug. 31, 2022 (JP) 2022-138850
Aug. 31, 2022 (JP) 2022-138851
Aug. 31, 2022 (JP) 2022-138852

(51) Int. Cl. H10W 10/10; H10D 86/00; H10P 90/00; H10W 10/00; H10W 10/17

(52) U.S. Cl. CPC H10W 10/181; H10D 86/201; H10P 90/1914; H10W 10/061; H10W 10/17

(57) ABSTRACT

To provide a crystal having excellent crystallinity, a laminated structure, and an element, an electronic device, an electronic apparatus, and a system using the crystal and the laminated structure.

To manufacture a laminated structure by forming at least a compound film on a crystal substrate, and then laminating a crystal film containing a crystal made of a crystalline metal compound products containing a metal compound containing compound products of Hf, Zr, and Si as a main component, the lamination being performed by forming the crystal film using compound elements in the compound film.

### TECHNICAL FIELD

The present invention relates to a crystal, a laminated structure, an element, an electronic device, an electronic apparatus, and a system.

### BACKGROUND ART

Conventionally, there is a known silicon on insulator (SOI) technology in which isolation between elements is performed using an SiO₂ film for the purpose of preventing lateral or vertical malfunction and destruction of ICs due to parasitic elements occurred in PN isolation. In recent years, the formation of a plurality of semiconductor elements with different withstand voltages on a single semiconductor substrate has also been considered, especially for wide bandgap semiconductors (for example, SiC, GaN or the like) (Patent Literature 1).

Attempts have been further made to form devices on flexible substrates such as plastics using SOI technology. For example, Patent Literature 2 discloses a method in which a window is partially opened in an SOI layer using a completed SOI substrate to expose a buried oxide (BOX) layer and then HF etching is performed and HF permeates laterally to etch the BOX and form pillars. There is a method in which after forming the pillars, the SOI layer is attached to polyethylene terephthalate (PET) or the like, peeled off from the substrate with the pillar portion as a boundary and formed on PET or the like so that the SOI layer on which a device has been manufactured is transferred onto a flexible substrate.

However, none of the SOI technologies is satisfactory in terms of the crystallinity of a semiconductor film formed on an insulating film, the crystallinity or insulating characteristics of the insulating film, or the like. Therefore, more excellent crystallinity and more excellent semiconductor characteristics have been desired. With the SOI layer as the buffer layer, SOI technologies that can provide excellent crystallinity not only for semiconductors but also for piezoelectric substances or the like have also been desired. Furthermore, when peeling and transferring the SOI layer, the process becomes complicated or the peeling is difficult. Therefore, new SOI technologies for easy peeling and transfer have been desired.

### CITATION LIST

### Patent Literature

Patent Literature 1: Japanese Unexamined Patent Publication No. 2021-5718

Patent Literature 2: Japanese Unexamined Patent Publication No. 2014-179580

### SUMMARY OF INVENTION

### Technical Problem

An object of the present invention is to provide a crystal having excellent crystallinity, a laminated structure as well as an element, an electronic device, an electronic apparatus, and a system that use the crystal and the laminated structure.

### Solution to Problem

As a result of intensive studies to achieve the above object, the present inventors have made various findings that when forming at least a compound film on a crystal substrate, and then laminating a crystal film, which contains a crystal made of a crystalline metal compound containing a metal compound containing compounds of Hf, Zr, and Si as a main component, the lamination is performed by forming the crystal film using the compound elements in the compound film, thereby easily obtaining a crystal having excellent crystallinity and a laminated structure; that when a conductive film or a semiconductor film, and then a piezoelectric film is formed on the crystal, the crystal and the laminated structure will have excellent crystallinity and extremely excellent electrode characteristics and various characteristics of functional films; that the crystal and the laminated structure are particularly suitable as a buffer layer for forming functional films; and that the crystal and the laminated structure are also useful for peeling and transfer. The present inventors have found that such a crystal and a laminated structure can solve the above-described conventional problems at once.

The present inventors further investigated and completed the present invention based on the above findings.

That is, the present invention relates to the following inventions.
[1] A crystal made of a crystalline metal compound containing a metal compound as a main component, wherein the metal compound includes compounds of Hf, Zr, and Si.
[2] The crystal according to [1], wherein the crystalline metal compound has a cubic or hexagonal crystal structure.
[3] The crystal according to [2], wherein the crystalline metal compound is oriented in a (111), (100), (010) or (0001) direction.
[4] The crystal according to any one of [1] to [3], wherein the crystalline metal compound contains 5 or more atomic percent of a compound of Si with respect to the crystalline metal compound.
[5] The crystal according to any one of [1] to [4], wherein the crystalline metal compound contains 50 or more atomic percent of both a compound of Hf and a compound of Zr with respect to the crystalline metal compound.
[6] The crystal according to any one of [1] to [5], being a ferroelectric.
[7] The crystal according to any one of [1] to [6], being in a form of a film.
[8] The crystal according to [7], having a film thickness of 1 μm or more.
[9] A laminated structure, having a crystal film laminated on a crystal substrate directly or with another layer interposed therebetween, wherein the crystal film is made of the crystal according to any one of [1] to [8].
[10] The laminated structure according to [9], wherein the crystal film constitutes a part or the whole of a buffer layer and is a substrate for crystal growth.
[11] An element having a crystal or a laminated structure, wherein the crystal is the crystal according to any one of [1] to [8], or the laminated structure is the laminated structure according to [9] or [10].
[12] The element according to [11], being a piezoelectric element or a semiconductor element.
[13] An electronic device having a crystal or a laminated structure, wherein the crystal is the crystal according to any one of [1] to [8], or the laminated structure is the laminated structure according to [9] or [10].
[14] The electronic device according to [13], being a piezoelectric device or a semiconductor device.
[15] An electronic apparatus having an electronic device, wherein the electronic device is the electronic device according to [13] or [14].
[16] A system having an electronic apparatus, wherein the electronic apparatus is the electronic apparatus according to [15].
[17] A method of manufacturing a laminated structure, including: forming at least a compound film on a crystal substrate and then laminating a crystal film, which contains a crystal made of a crystalline metal compound containing a metal compound as a main component, on the compound film, wherein the lamination is performed by forming the crystal film using compound elements in the compound film.
[18] The manufacturing method according to [17], wherein the metal compound includes compounds of Hf, Zr, and Si.
[19] The laminated structure according to [9], between the crystal substrate and the crystal film, having an amorphous thin film that contains the constituent metals of the crystal film and/or the crystal substrate, and/or one or more buried layers that are embedded in a part of the crystal substrate and contain the constituent metals.
[20] The laminated structure according to [19], between the crystal substrate and the crystal film, having an amorphous thin film that contains the constituent metals of the crystal film and/or one or more buried layers that are embedded in a part of the crystal substrate and contain the constituent metals of the crystal film.
[21] The laminated structure according to [19], between the crystal substrate and the crystal film, having an amorphous thin film that contains the constituent metals of the crystal film and/or the crystal substrate, and/or one or more buried layers that are embedded in a part of the crystal substrate and contain the constituent metals.
[22] The laminated structure according to any one of [19] to [21], wherein the constituent metal includes Hf.
[23] The laminated structure according to any one of [19] to [22], wherein the amorphous thin film has a film thickness of 1 nm to 10 nm inclusive.
[24] The laminated structure according to any one of [19] to [23], wherein the buried layer has an approximately inverted triangular cross-sectional shape.
[25] An electronic device, an electronic apparatus, or a system having a laminated structure, wherein the laminated structure is the laminated structure according to any one of [19] to [24].
[26] A crystal made of a crystalline metal compound containing a metal compound as a main component, wherein the metal compound contains Hf and/or Zr and Si.
[27] A crystal made of a crystalline metal compound containing a metal compound as a main component, wherein the metal compound contains Hf and Si.

### Advantageous Effects of Invention

The crystal and the laminated structure of the present invention have excellent crystallinity, and element, electronic device, electronic apparatus, and system using the crystal and the laminated structure have favorable characteristics of their respective functional films.

### BRIEF DESCRIPTION OF DRAWINGS

FIG. 1 is a diagram schematically illustrating an example of a preferred embodiment of a laminated structure of the present invention.

FIG. 2 is a diagram schematically illustrating an SOI island forming step in the peeling and transfer as an example of a preferred application of the laminated structure of the present invention.

FIG. 3 is a diagram schematically illustrating an HF etching step in the peeling and transfer as an example of a preferred application of the laminated structure of the present invention.

FIG. 4 is a diagram schematically illustrating an attaching step of attaching to a flexible substrate in the peeling and transfer as an example of a preferable application of the laminated structure of the present invention.

FIG. 5 is a diagram schematically illustrating a peeling step in the peeling and transfer as an example of a preferred application of the laminated structure of the present invention.

FIG. 6 is a diagram schematically illustrating an example of an oxide film forming step in a preferred method of manufacturing the laminated structure of the present invention.

FIG. 7 is a diagram schematically illustrating an example of an insulating film forming step in a preferred method of manufacturing the laminated structure of the present invention.

FIG. 8 shows a cross-sectional STEM image observed in an example.

FIG. 9 shows the results of XPS analysis in an example.

FIG. 10 is a diagram schematically illustrating a preferred example of an insulated gate bipolar transistor (IGBT) obtained in the present invention.

FIG. 11 is a diagram schematically illustrating an example of a preferred step for manufacturing the insulated gate bipolar transistor (IGBT) illustrated in FIG. 10.

FIG. 12 is a diagram schematically illustrating a preferred example of a power supply system.

FIG. 13 is a diagram schematically illustrating a preferred example of a system device.

FIG. 14 is a diagram schematically illustrating a preferred example of a power supply circuit diagram of a power supply device.

FIG. 15 is a diagram schematically illustrating a film forming apparatus preferably used in an example.

FIG. 16 shows a cross-sectional STEM image measured in an example.

FIG. 17 shows a STEM image measured in an example.

FIG. 18 shows a STEM image of a buried layer measured in an example.

FIG. 19 shows XRD measurement results measured in an example.

### DESCRIPTION OF EMBODIMENTS

A crystal according to the present invention is a crystal made of a crystalline metal compound containing a metal compound as a main component, wherein the metal compound includes compounds of Hf, Zr and Si. The crystal may be a single crystal or a polycrystal. In the present invention, it is preferable that the crystal is a crystal made of a crystalline metal compound containing a metal compound as a main component, wherein the metal compound is a crystal containing Hf and/or Zr and Si, and it is more preferable that the metal compound contains Hf and Si.

The crystalline metal compound is not particularly limited as long as it contains the metal compound as a main component, and it is preferable that the metal compound includes compounds of Hf, Zr, and Si. The “main component” may include the compounds of Hf, Zr, and Si as long as the atomic ratio of Hf, Zr and Si with respect to all the metal elements in the metal compound in the crystal is 0.5 or more. In the present invention, it is preferable that the atomic ratio of Hf, Zr and Si with respect to all the metal elements in the metal compound is 0.7 or more, and more preferably 0.8 or more.

In the present invention, it is preferable that the crystalline metal compound has a cubic or hexagonal crystal structure, and it is more preferable that the crystalline metal compound is oriented in a (111), (100), (010) or (0001) direction. In the present invention, it is preferable that the crystalline metal compound contains 5 or more atomic percent of a compound of Si with respect to the crystalline metal compound, and more preferably 50 or more atomic percent of both a compound of Hf and a compound of Zr with respect to the crystalline metal compound.

According to such a preferable range, it is preferable that the crystalline metal compound not only can be used as an excellent buffer layer, but also can exhibit favorable characteristics as a ferroelectric, and further can achieve more excellent electric characteristics (particularly, the interface between the conductor layer and the insulating layer). The crystalline metal compound may also be known compounds such as oxides, nitrides, oxynitrides, sulfides, oxysulfides, borides, oxyborides, carbides, oxycarbides, boron carbides, boron nitrides, boron sulfides, carbonitrides, carbosulfides or carboborides, and in the present invention, the compounds are oxides or nitrides, which are more excellent as buffer layers for stress relaxation and warpage reduction in, for example, heteroepitaxial growth. In the present invention, it is preferable that the crystalline metal compound is a crystalline metal oxide, the compound film is an oxide film, and the compound element is oxygen. In the present invention, it is preferable that the crystalline metal compound is a crystalline metal oxide, the compound film is an oxide film, and the compound element is oxygen.

Further, in the present invention, it is preferable that the crystalline metal compound is a crystalline nitride, that the compound film is a nitride film, and that the compound element is nitrogen.

In the present invention, it is preferable that the crystal is in a form of a film (hereinafter also referred to as “crystal film”), and when the crystal is in a form of a film, it is preferable that the film thickness is 1 μm or more in terms of withstand voltage. When forming at least an oxide film on a crystal substrate and then laminating a crystal film containing a crystal made of a crystalline metal oxide containing metal oxides as a main component, such a preferable crystal can be easily obtained by laminating the crystal film formed using oxygen atoms in the oxide film. The method of forming the crystal film is not particularly limited, and may be a known method (for example, an MBE method, an ion plating method and the like), and the crystal growth conditions also can be appropriately set. The laminated structure obtained by the above method and the method of manufacturing the same are also included in the present invention.

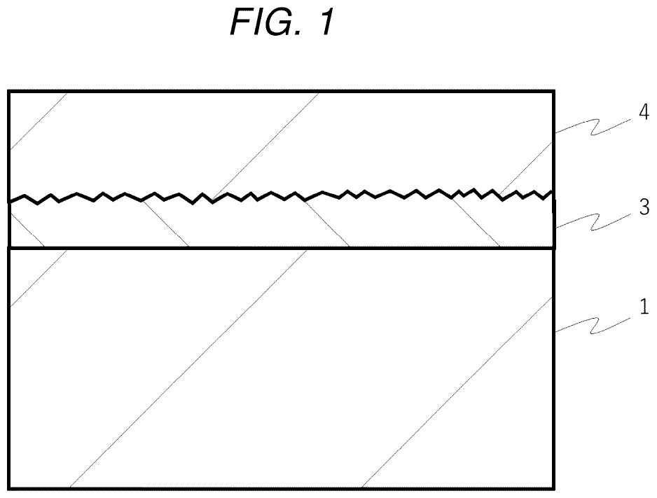

FIG. 1 illustrates a preferred example of the laminated structure, wherein the crystal in a form of a film is laminated as a first epitaxial layer 3 on a crystal substrate 1 using an oxide film, and a conductive film, a semiconductor film, or a piezoelectric film are laminated as a second epitaxial layer 4 on the first epitaxial layer 3. In the present description, the terms “film” and “layer” may be interchanged with each other depending on the case or condition. Oxides are given as preferred examples of the laminated structure, but the present invention is not limited to these preferred examples and can preferably use various compounds such as nitrides.

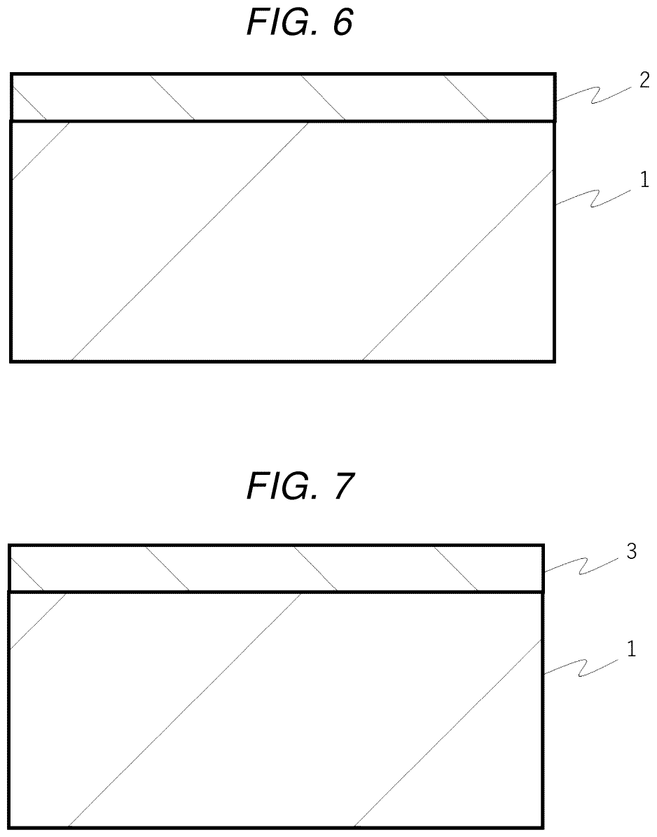

The laminated structure can be easily manufactured by, for example, forming an oxide film 2 of the crystal substrate 1 on the crystal substrate 1 as illustrated in FIG. 6, and then forming the crystal film 3 (the first epitaxial layer) made of the crystalline metal oxide on the crystal substrate 1 using oxygen in the oxide film 2 as illustrated in FIG. 7. In the present invention, the laminated structure may have the oxide film 2 on the crystal substrate 1, but when the crystal film 3 is formed, all oxygen in the oxide film 2 may be absorbed and the oxide film 2 may disappear. Hereinafter, preferred embodiments of the present invention will be described more specifically, but the present invention is not limited to these specific examples.

The crystal substrate (hereinafter also simply referred to as “substrate”) is not particularly limited as long as the substrate material and the like do not interfere with the object of the present invention, and may be a known crystal substrate. The substrate material may be an organic compound or an inorganic compound. In the present invention, it is preferable that the crystal substrate contains an inorganic compound. In the present invention, it is preferable that the substrate has crystals on a part or the whole of the surface, it is more preferable that the crystal substrate has crystals on the whole or part of the main surface on the crystal growth side, and it is most preferable that the crystal substrate has crystals on the whole main surface on the crystal growth side. The crystal is not particularly limited as long as it does not interfere with the object of the present invention, and the crystal structure is also not particularly limited, and the crystal is preferably a cubic, tetragonal, trigonal, hexagonal, orthorhombic, or monoclinic crystal, more preferably a cubic or hexagonal crystal, and most preferably oriented in a (111), (100), or (0001) direction. The crystal substrate may have an off angle, the off angle may include an off angle of 0.2° to 12.0° inclusive. Here, the “off angle” refers to an angle formed between the substrate surface and the crystal growth plane. The shape of the substrate is not particularly limited as long as it is plate-shaped and serves as a support for the insulating film. The substrate may be an insulating substrate or a semiconductor substrate, and in the present invention, it is preferable that the substrate is a Si substrate, more preferably a crystalline Si substrate, and most preferably a crystalline Si substrate that is oriented in a (111), (100), or (0001) direction. The substrate material may include, in addition to the Si substrate, for example, one or more metals belonging to Groups 3 through 15 of the Periodic Table or oxides of these metals. The shape of the substrate is not particularly limited, and may be an approximately circular shape (for example, a circle or an ellipse) or a polygonal shape (for example, a triangle, a square, a rectangle, a pentagon, a hexagon, a heptagon, an octagon, or a nonagon) as well as other suitable shapes.

Further, in the present invention, it is preferable that the crystal substrate has a flat surface, more preferably a concavo-convex shape on a part or the whole of the surface, as the quality of the crystal growth of the crystal film will be more excellent. The crystal substrate having the concavo-convex shape may have a concavo-convex portion formed of a concave portion or a convex portion on a part or the whole of the surface, and the concavo-convex portion is not particularly limited as long as the concavo-convex portion is formed of a convex portion or a concave portion. The concavo-convex portion may be formed of a convex portion, a concave portion, or both a convex portion and a concave portion. The concavo-convex portion may also be formed of a regular convex portion or concave portion, or may be formed of an irregular convex portion or concave portion. In the present invention, it is preferable that the concavo-convex portion is formed repeatedly, and more preferably patterned repeatedly and regularly. The shape of the concave-convex portion is not particularly limited, which may include a stripe-shape, a dot-shape, a mesh-shape, and a random-shape. In the present invention, the dot-shape or the stripe-shape is preferable, and the dot-shape is more preferable. When the concavo-convex portion is repeatedly and regularly patterned, the pattern shape of the concavo-convex portion is preferably a circular shape, an elliptical shape and a polygonal shape such as a triangle, a quadrangle (for example, a square, a rectangle, or a trapezoid), a pentagon, or a hexagon. When the concavo-convex portion is formed in a dot-shape, the lattice shape of the dot is preferably a lattice shape such as a square lattice, an orthorhombic lattice, a triangular lattice, or a hexagonal lattice, and more preferably a triangular lattice. The cross-sectional shape of the concave portion or the convex portion of the concavo-convex portion is not particularly limited, which may include an angular U-shape, a U-shape, an inverted U-shape, a wave-shape or a polygon such as a triangle, a quadrangle (for example, a square, a rectangle, or a trapezoid), a pentagon or a hexagon. The thickness of the crystal substrate is not particularly limited, but is preferably 50 μm to 2000 μm inclusive, and more preferably 100 μm to 1000 μm inclusive.

The oxide film is not particularly limited as long as oxygen atoms in the oxide film can be absorbed by the crystal film, and usually contains an oxide material. The oxide material is not particularly limited as long as it does not interfere with the object of the present invention, and may be a known oxide material. The oxide material may include an oxide of a metal or a metalloid.

In the present invention, the oxide film preferably contains an oxide material of the crystal substrate, and such an oxide film may include a thermal oxide film and a natural oxide film of the crystal substrate. Further, in the present invention, the oxide film may be a sacrificial layer in which part or the whole of the film disappears or is destroyed when oxygen atoms are absorbed, and in the present invention, the oxide film is preferably an oxygen supply sacrificial layer in which oxygen atoms are absorbed and the oxide film itself disappears during crystal growth of the epitaxial layer. In addition, the oxide film may be patterned, for example, in a stripe-shape, a dot-shape, a mesh-shape, or a random-shape. The thickness of the oxide film is not particularly limited, but is preferably more than 1 nm and less than 100 nm.

The crystal film (first epitaxial layer) preferably includes an epitaxial film into which oxygen atoms in the oxide film are absorbed. The “epitaxial film into which oxygen atoms in the oxide film are absorbed” means that oxygen atoms in the oxide film are deprived by the epitaxy film during the crystal growth of the epitaxial film. In the present invention, the crystal film preferably contains a neutron absorber. The neutron absorber may be a known neutron absorber, and in the present invention, by using such neutron absorber to absorb oxygen in the oxide film, it is possible to make the adhesiveness and the crystallinity, and further the characteristics of the functional film, or the like more excellent. Preferred examples of the neutron absorber include hafnium (Hf) or the like.

In the present invention, a second epitaxial layer made of a conductive film, a semiconductor film, or a piezoelectric film is preferably laminated on the crystal film directly or with another layer interposed therebetween. By laminating the layers in this manner, the first epitaxial layer can be regularly transformed at the interface between the first epitaxial layer and the second epitaxial layer in a manner of having a lattice constant approximately equal to that of the second epitaxial layer. Preferred examples of the mode of the regular transformation include a transformation in which the shape is deformed into a peak-valley structure, and in the present invention, the angles formed between the top point and the bottom point adjacent to each other in the peak-valley structure are preferably different from each other, and the angles are more preferably each within a range of 30° to 45° inclusive. Here, the first epitaxial layer usually has a first crystal plane and a second crystal plane, but since a difference in lattice constant between the first crystal plane and the second crystal plane may occur due to the transformation, the difference in lattice constant between the first crystal plane and the second crystal plane is preferably within a range of 0.1% to 20% inclusive. In the present invention, since the first crystalline plane can have a lattice constant that is approximately the same as that of the second epitaxial layer, the difference in lattice constant between the first epitaxial layer and the second epitaxial layer can be easily set within a range of 0.1% to 20% inclusive.

In the present invention, when a conductive film is laminated on the crystal film and the conductive film is formed of a single crystal film of a conductive metal, a large-area defect-free film can be easily obtained, and not only the function as an electrode but also the characteristics of elements can be made more excellent.

The conductive metal is not particularly limited as long as it does not interfere with the object of the present invention, and it may contain gold, silver, platinum, palladium, silver-palladium, copper, nickel, and alloys thereof, and in the present invention, it is preferable that the conductive metal contains platinum. In the present invention, according to the above manufacturing method, a defect-free single crystal film can be preferably obtained as an electrode in an area of 100 nm² or more, and more preferably in an area of 1000 nm² or more. Further, a single crystal film having a thickness of preferably 100 nm or more can be easily obtained as an electrode. When the conductive film formed of a single crystal film of a conductive metal is laminated on the crystal film, the laminated structure can be preferably used as an electrode substrate in which a crystalline conductive film is laminated on the insulating film.

The semiconductor film is not particularly limited as long as it contains a semiconductor, and may be a known semiconductor film, and in the present invention, it is preferable that the semiconductor film contains a cubic crystal semiconductor. Examples of the cubic crystal semiconductor include c-BN, c-AIN, c-GaN, c-InN, c-Sic, GaAs, AlAs, InAs, GaP, AlP, InP, and mixed-crystal semiconductors thereof.

The piezoelectric film is not particularly limited as long as it is made of a piezoelectric material, and may be a film made of a known piezoelectric material, and in the present invention, it is preferable that the piezoelectric film is made of a piezoelectric material having a trigonal or hexagonal crystal structure. Examples of the piezoelectric material include lead zirconate titanate (PZT) and other types of ceramic materials having a so-called perovskite structure represented by ABO₃, such as barium titanate, lead titanate, potassium niobate, lithium niobate, lithium tantalate, sodium tungstate, zinc oxide, barium strontium titanate (BST), strontium bismuth tantalate (SBT), lead metaniobate, lead zinc niobate, and lead scandium niobate, or polyvinylidene fluoride and quartz crystal.

The film thickness of each of the conductive film, the semiconductor film, and the piezoelectric film is not particularly limited, but is preferably 10 nm to 1000 μm inclusive, and more preferably 10 nm to 100 μm inclusive.

The laminated structure can be easily obtained by a method of manufacturing a laminated structure in which an insulating film is laminated on a crystal substrate with at least an oxide film interposed therebetween, wherein the lamination is performed at 350 °C to 700 °C inclusive by forming a crystal film using oxygen atoms in the oxide film. When the temperature is in the range of 350 °C to 700 °C inclusive, oxygen atoms in the oxide film can be easily absorbed into the crystal film to grow the crystal.

In the present invention, it is preferable that the crystal film is formed using oxygen gas after using oxygen atoms in the oxide film for the lamination. By forming the film in this manner, it is possible to easily obtain a laminated structure in which the crystal film is laminated on the crystal substrate, between the crystal substrate and the crystal film, the laminated structure having an amorphous thin film that contains the constituent metals of the crystal film, and/or the crystal substrate and/or one or more buried layers that are embedded in a part of the crystal substrate and contain the constituent metals. In the present invention, it is preferable that the laminated structure has both the amorphous layer and the buried layer, thereby further making the functionality of the crystal film more excellent. Further, it is preferable that the amorphous layer and the buried layer each contains constituent metals of the crystal film, thereby further making the crystallinity of the crystal film more excellent. In addition, in the present invention, it is preferable that the constituent metal includes Hf, thereby improving stress relaxation and further realizing stress relaxation in multiple stages. In the present invention, it is preferable that the thickness of the amorphous thin film is 1 nm to 10 nm inclusive so that the crystallinity of the crystal film can be further enhanced, and the amorphous thin film having such a preferable thickness can be easily obtained by the preferable manufacturing method according to the present invention. In the present invention, it is preferable that the shape of the buried layer has an approximately inverted triangular cross-sectional shape, which allows for higher functionality of the crystal film. These preferable laminated structures can be easily obtained by appropriately adjusting the film thickness of the oxide film and the introduction timing of the oxygen gas.

As the laminating means used in the lamination, the film forming means of the insulating film is usually preferably used, and the film forming means may be a known film forming means. In the present invention, it is preferable that the film forming means is vapor deposition or sputtering.

The laminated structure obtained as described above can be used for an element as it is or after being further processed as desired according to conventional methods.

When the laminated structure is used for the element, the laminated structure may be used as it is, or may be used after other layers (for example, an insulator layer, a semi-insulator layer, a conductor layer, a semiconductor layer, a buffer layer or other intermediate layers) are further formed. In the present invention, it is preferable that the laminated structure is used as an SOI substrate in which a functional film (for example, a semiconductor film, a piezoelectric film) is laminated on the crystal film.

The element is used in, for example, an electronic device (preferably a piezoelectric device) according to conventional methods. More specifically, for example, various electronic devices can be configured by connecting the element as a piezoelectric element to a power supply or an electric/electronic circuit and mounting or packaging the element on a circuit substrate. In the present invention, it is preferable that the electronic device is a piezoelectric device, and more preferably, for example, a piezoelectric device in an electronic apparatus such as a gyroscope or a motion sensor. Further, for example, when connected and packaged with an amplifier and a rectifier circuit, it can be used for various sensors such as a magnetic sensor.

The electronic device is preferably used in an electronic apparatus according to conventional methods. Preferred examples of the electronic apparatus in which the electronic device can be used include various electronic apparatuses other than the above-described electronic apparatuses, and more specifically, for example, a liquid discharge head, a liquid discharge apparatus, a vibration wave motor, an optical apparatus, a vibration apparatus, an imaging apparatus, a piezoelectric acoustic component, a sound reproducing apparatus having the piezoelectric acoustic component, a sound recording apparatus, a mobile phone and various information terminals and the like.

In the present invention, it is preferable that the element is a semiconductor element, and the electronic device is a semiconductor device. The semiconductor element or the semiconductor device (hereinafter also collectively referred to as a “semiconductor device”) is not particularly limited as long as it does not interfere with the object of the present invention, and may be a known semiconductor element or semiconductor device. The semiconductor device may be a vertical device or a lateral device, and in the present invention, it is preferable that the semiconductor device a lateral device. Examples of the semiconductor device include a diode or a transistor (for example, an MOSFET or a JFET), but an insulated gate semiconductor device (for example, a MOSFET or an IGBT) or a semiconductor device having a Schottky gate (for example, an MESFET) is preferable, a MOSFET and/or an IGBT is more preferable, and a lateral MOSFET and/or a lateral IGBT is most preferable.

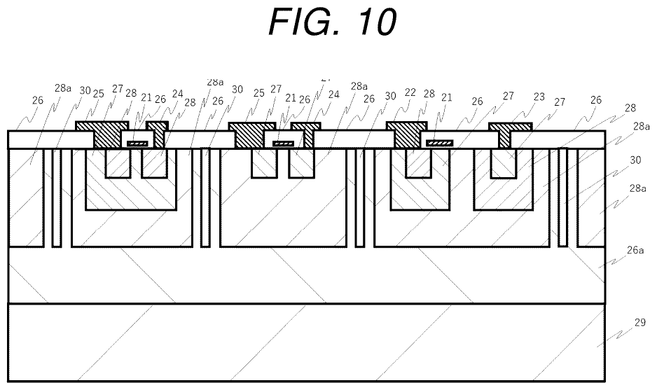

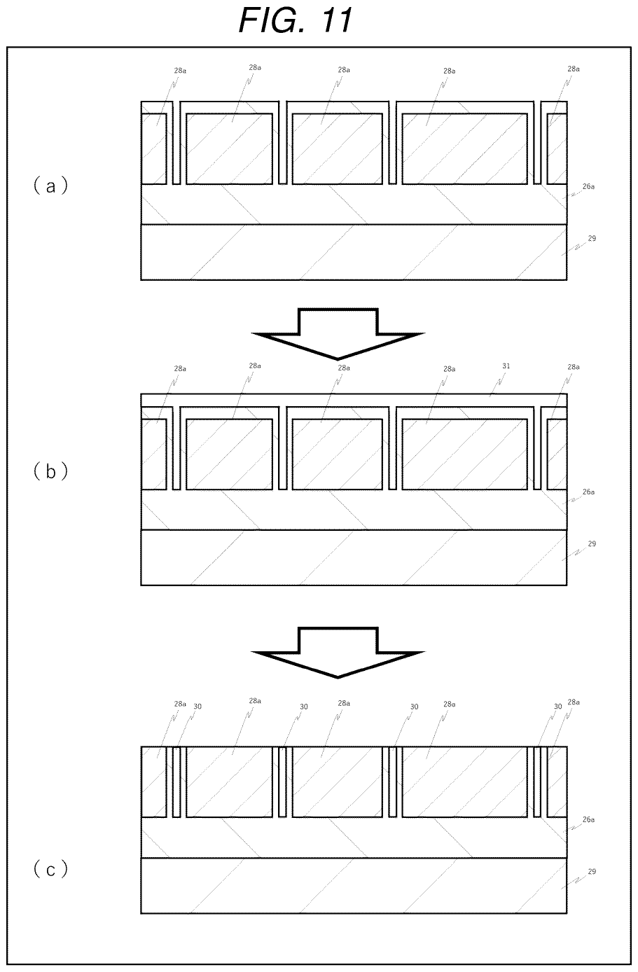

FIG. 10 illustrates a lateral IGBT, a lateral NMOS, and a lateral PMOS which are preferable in the present invention. As illustrated in FIG. 1, in the lateral IGBT, the lateral NMOS, and the lateral PMOS, an insulating film 26a as the crystal film is formed on a crystal substrate 29, and each element is provided on the insulating film 26a. As illustrated in FIG. 10, the lateral IGBT includes a gate electrode 21, an emitter electrode 22, a collector electrode 23, an insulating film 26 as the crystal film, a p-type semiconductor 27, an n-type semiconductor 28, and an n-type semiconductor 28a. As illustrated in FIG. 10, the NMOS includes a gate electrode 21, a drain electrode 24, a source electrode 25, an insulating film 26, a p-type semiconductor 27, an n-type semiconductor 28, and an n-type semiconductor 28a. As illustrated in FIG. 10, the PMOS includes a gate electrode 21, a drain electrode 24, a source electrode 25, an insulating film 26, a p-type semiconductor 27, and an n-type semiconductor 28a.

FIG. 11 illustrates a preferable manufacturing process of the insulated gate bipolar transistor (IGBT) as illustrated in FIG. 10. In the manufacturing process of FIG. 11, a laminated structure is adopted, in which the insulating film 26a as the crystal film is formed on the crystal substrate 29 and the n-type semiconductors 28a (for example, an Si semiconductors) are further formed on the insulating film 26a. In FIG. 11 (a), a trench is provided in the laminated structure by using known means, and further, the surfaces of the n-type semiconductors 28a (for example, Si semiconductors) are oxidized by using known means. In FIG. 11 (b), the laminated structure illustrated in FIG. 11 (a) is processed with a polysilicon 31 by using known means to fill the trench with the polysilicon 31, and a polysilicon layer is further formed on the oxidized surface. In FIG. 11 (c), the laminated structure illustrated in FIG. 11 (b) is polished using known means to obtain the laminated structure illustrated in FIG. 11 (c). The obtained laminated structure is subjected to a process of manufacturing various elements using known means.

In the lateral IGBT, the lateral NMOS, and the lateral PMOS thus obtained, element isolation by a trench isolation structure is applied, and it is also possible to have a small isolation area or directly configure an inverter by a power supply rectified and smoothed from a commercial power supply. Then, the high-withstand-voltage output unit and the control circuit unit can be configured on the same chip, thereby realizing an excellent power IC. In particular, since each device inside the IC is completely isolated from each other by the dielectric, it is possible to eliminate the influence of the parasitic element and to realize a highly reliable system.

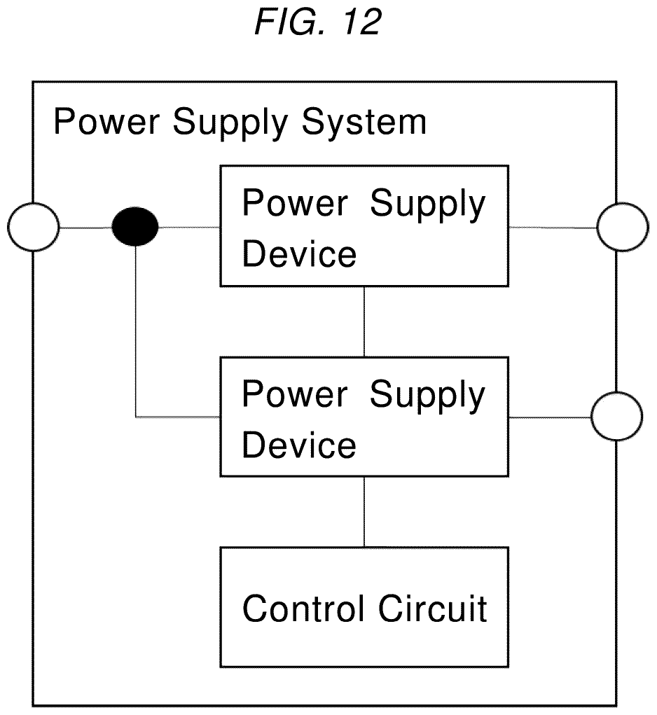

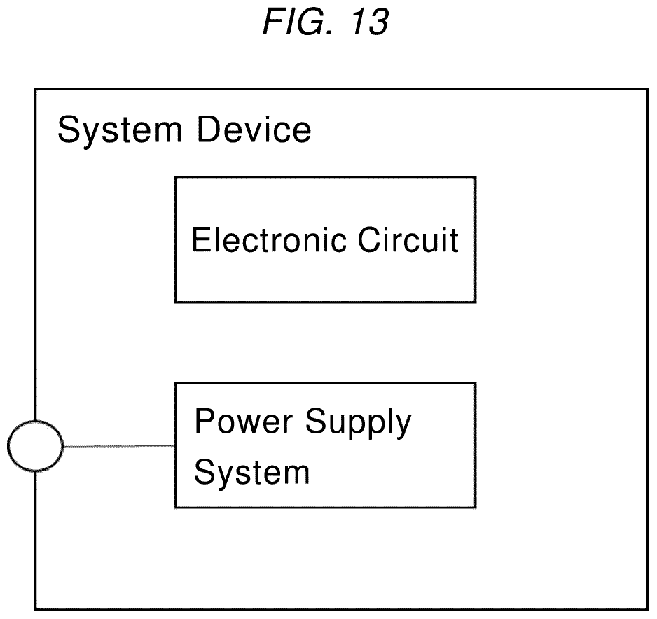

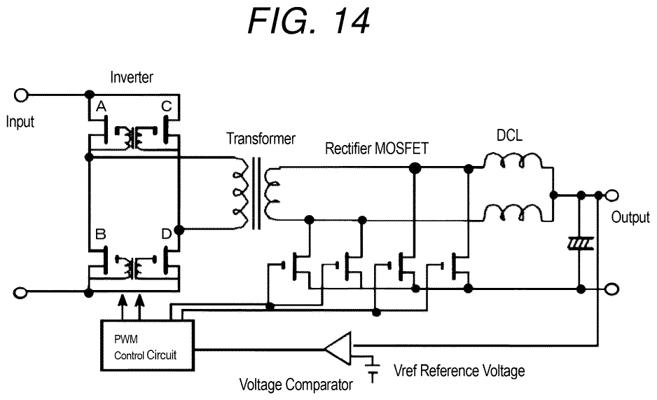

In addition to the above, the semiconductor device is preferably used as a semiconductor device such as a power module, an inverter, or a converter by using known means, and is further preferably used as a semiconductor device in, for example, a semiconductor system using a power supply device. The power supply device can be manufactured, for example, by connecting the semiconductor device to wiring patterns or the like using known means. FIG. 12 illustrates an example of a power supply system. FIG. 12 illustrates a power supply system including a plurality of the power supply devices and a control circuit. FIG. 13 illustrates that the power supply system can be used in a system device in combination with an electronic circuit. FIG. 14 illustrates an example of a power supply circuit diagram of the power supply device. FIG. 14 illustrates a power supply circuit of a power supply device including a power circuit and a control circuit. After an inverter (configured by MOSFETS A to D) switches a DC voltage at a high frequency to convert it into AC, insulation and transformation are performed by a transformer, and after being rectified by rectifier MOSFETS (A to B′), DCL (smoothing coils L1 and L2) and capacitors are used to smooth and the power supply device outputs DC voltage. At this time, the voltage comparator compares the output voltage with the reference voltage, and the PWM control circuit controls the inverter and the rectification MOSFET so as to obtain a desired output voltage.

### EXAMPLES

### Example 1

The crystal growth plane of an Si substrate (100) was processed by RIE, and was heated in the presence of oxygen to form a thermal oxide film, and then metals of a vapor deposition source and oxygen in the oxide film on the Si substrate were thermally reacted by a vapor deposition method without using oxygen to form a single crystal of a crystalline metal oxide on the Si substrate. Then, a single crystal film of the crystalline metal oxide was formed by the vapor deposition method with oxygen supplied, temperature lowered, and pressure increased. The conditions of the vapor deposition method during the film formation were as follows.
Vapor deposition source: Hf, Zr, Si
Voltage: 3.5 V to 4.75 V
Pressure: 3×10⁻² pa to 6×10⁻² pa
Substrate temperature: 450 °C to 700 °C

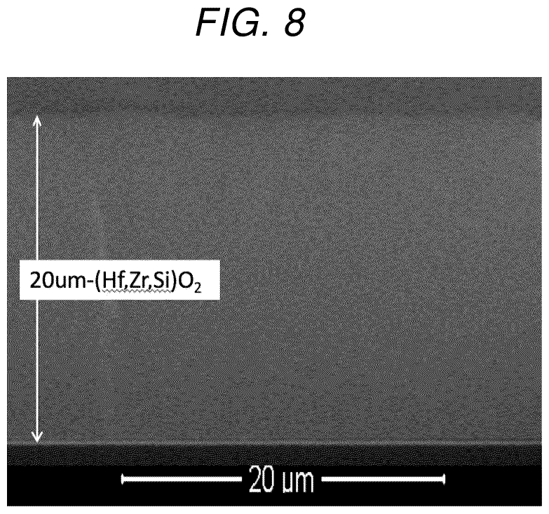

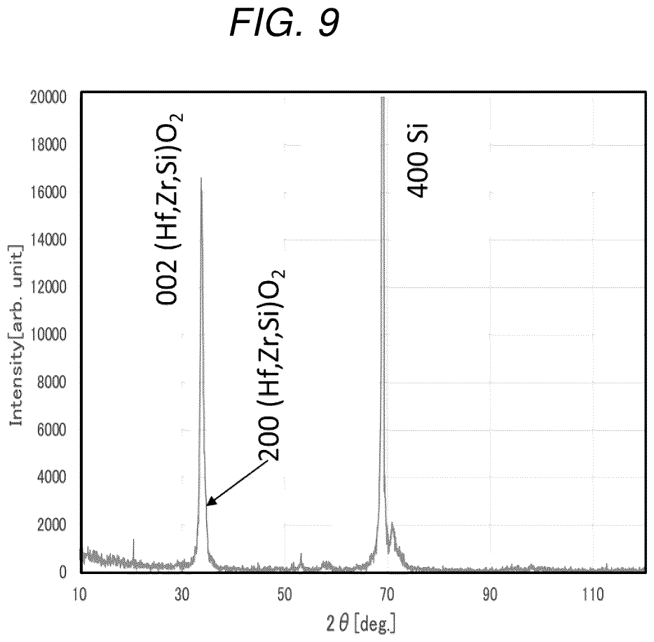

The obtained laminated structure was a laminated structure including a crystal film having excellent adhesiveness and crystallinity, and the obtained crystal film had a film thickness of 20 μm and exhibited ferroelectricity. FIG. 8 shows a cross-sectional STEM image of the obtained laminated structure. When the obtained crystal film was examined using an X-ray diffractometer, it was found to be (Hf, Zr, Si)O₂. FIG. 9 shows the results of XPS analysis.

### Example 2

A laminated structure was obtained in the same manner as in Example 1 except that the Si substrate was replaced with (111). The obtained laminated structure was a laminated structure including a crystal film having excellent adhesiveness and crystallinity as in Example 1, and exhibited ferroelectricity. When the obtained crystal film was examined using an X-ray diffractometer, it was found to be (Hf, Zr, Si)O₂.

### Example 3

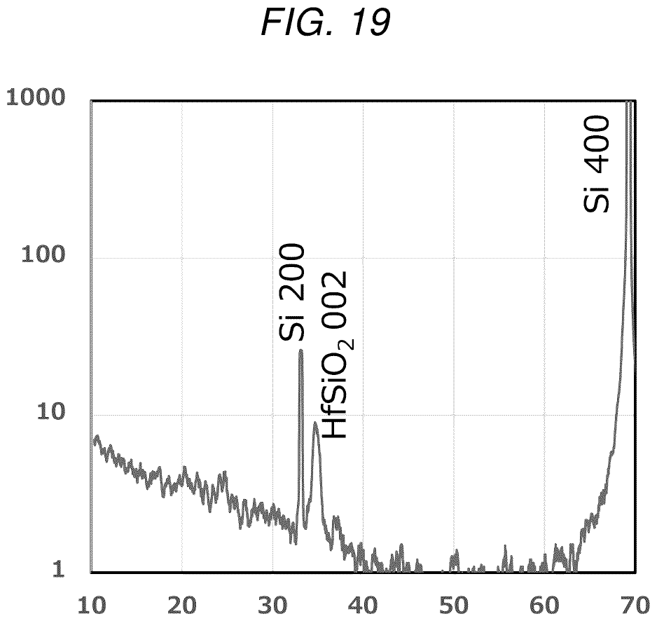

A laminated structure was obtained in the same manner as in Example 1 except that Zr was not used. The obtained laminated structure was a laminated structure including a crystal film having excellent adhesiveness and crystallinity as in Example 1, and exhibited ferroelectricity. When the obtained crystal film was examined using an X-ray diffractometer, it was found to be (Hf, Si)O₂ as shown in FIG. 19.

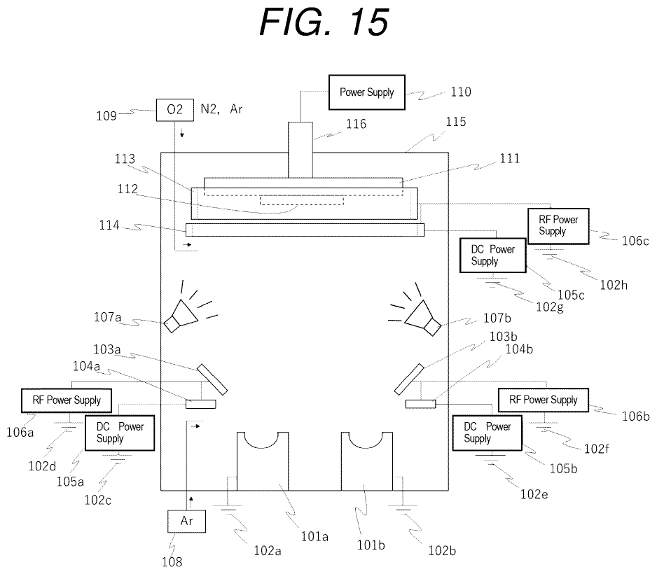

FIG. 15 illustrates a vapor deposition film forming apparatus used in Example 1. As illustrated in FIG. 15, the film forming apparatus includes at least metal sources 101a to 101b, earths 102a to 102h, ICP electrodes 103a to 103b, cut filters 104a to 104b, DC power supplies 105a to 105b, RF power supplies 106a to 106b, lamps 107a to 107b, an Ar source 108, a reactive gas source 109, a power supply 110, a substrate holder 111, a substrate 112, a cut filter 113, an ICP ring 114, a vacuum chamber 115, and a rotary shaft 116 in a crucible. The ICP electrodes 103a to 103b illustrated in FIG. 15 have an approximately concave surface shape or a parabolic shape curved toward the center of the substrate 112.

FIG. 15 illustrates that the substrate 112 is locked onto the substrate holder 111. Then, the rotary shaft 116 is rotated by using the power supply 110 and a rotating mechanism (not shown) to rotate the substrate 112. The substrate 112 is heated by the lamps 107a to 107b, and the vacuum chamber 115 is evacuated by a vacuum pump (not shown) to be vacuum or under a reduced pressure. Then, an Ar gas is introduced into the vacuum chamber 115 from the Ar source 108, and argon plasma is formed on the substrate 112 by using the DC power supplies 105a to 105b, the RF power supplies 106a to 106b, the ICP electrodes 103a to 103b, the cut filters 104a to 104b, and the earths 102a to 102h, thereby cleaning the surface of the substrate 112.

An Ar gas is introduced into the vacuum chamber 115 and a reactive gas is introduced using the reactive gas source 109. At this time, by alternately turning on and off the lamps 107a to 107b as lamp heaters, a crystal growth film of higher quality can be formed.

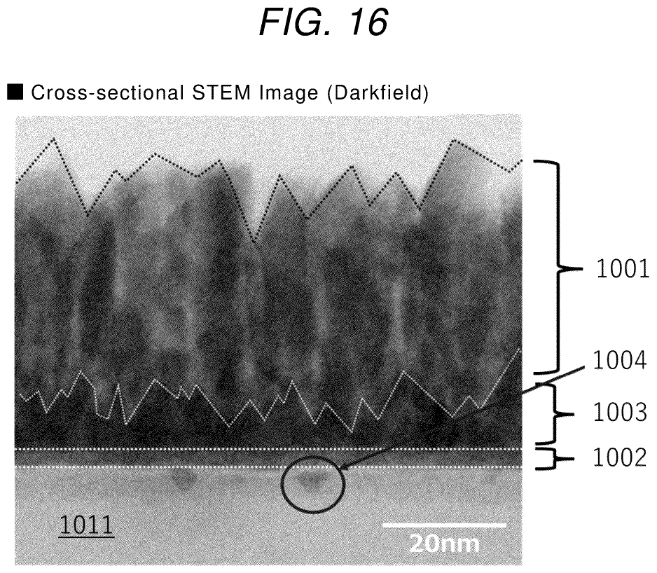

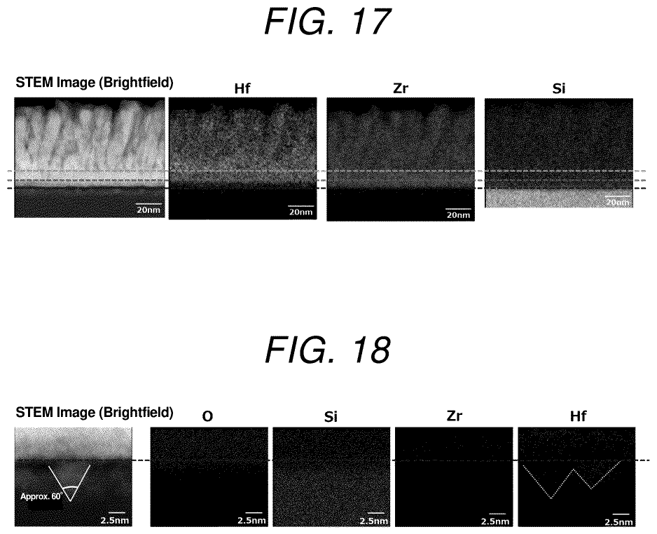

The laminated structure obtained in the same manner as in Example 1 was subjected to STEM analysis. A buried layer was formed between the crystal substrate and the crystal film, and amorphous layers (two layers) were further formed. A first amorphous layer on the crystal substrate contained Si and the constituent metal of the crystal film, Zr. A second amorphous layer contained Si of the crystal substrate and the constituent metals of the crystal film, Hf and Zr. As a reference example, FIGS. 16 to 18 show STEM analysis results of the laminated structure including the HfZrO mixed crystal manufactured in the same manner as in Example 1. FIG. 16 shows that between a crystal substrate 1011 and an epitaxial layer 1001, a buried layer 1004 is formed, and further amorphous layers 1002 and 1003 are formed. FIG. 17 shows that the first amorphous layer 1002 on the crystal substrate 1011 contains Si of the crystal substrate and the constituent metal of the epitaxial layer 1001, Zr. Furthermore, the second amorphous layer contains Si of the crystal substrate and the constituent metals of the epitaxial layer 1001, Hf and Zr. FIG. 18 shows that the buried layer 1004 has an approximately inverted triangular cross-sectional shape and is an oxide containing Hf and Si.

### Applications

Hereinafter, an example of the peeling and transfer, which is one of preferable applications of the obtained laminated structure, will be described in more detail with reference to the drawings, but the present invention is not limited to these applications. In the following applications, the crystal film is used as an insulating film. In the present invention, unless otherwise specified, an SOI substrate or an SOI semiconductor device can be manufactured from the laminated structure using known means.

FIG. 1 is a diagram illustrating a preferable example of a laminated structure of the present invention. In the laminated structure illustrated in FIG. 1, an insulating film 3 is formed on a crystal substrate 1, and a semiconductor layer is further formed as a second epitaxial layer 4 on the insulating film 3.

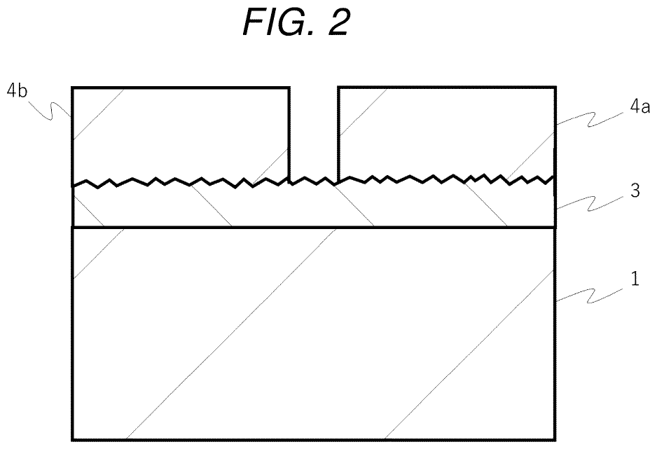

FIG. 2 illustrates a laminated structure obtained in an SOI island forming step in the peeling and transfer. In the SOI island forming step, the laminated structure illustrated in FIG. 1 is used as an SOI substrate, and photolithography is performed to partially remove the semiconductor layer (the second epitaxial layer) 4. In this way, the laminated structure illustrated in FIG. 2 is obtained. In the laminated structure illustrated in FIG. 2, the second epitaxial layer is separated into two islands, and a first island 4a and a second island 4b of the second epitaxial layer are formed on the insulating film 3.

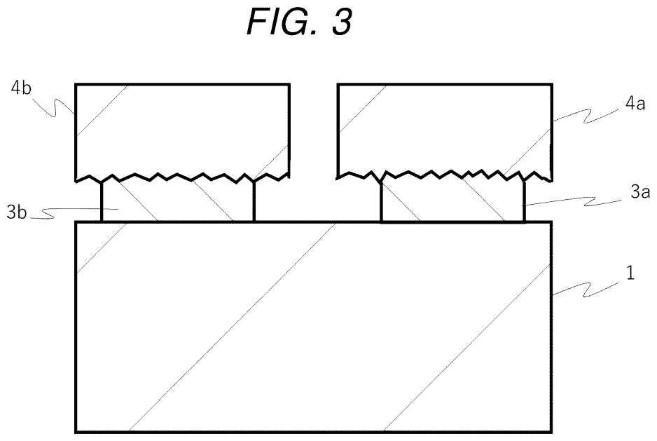

FIG. 3 illustrates a laminated structure obtained in an HF etching step in the peeling and transfer. In the HF etching step, a BOX layer is etched by HF to remain in a pillar shape using the laminated structure illustrated in FIG. 2. In the laminated structure illustrated in FIG. 3, an insulating film is formed in a pillar shape, and a first pillar 3a and a second pillar 3b of the insulating film (first epitaxial layer) each is formed on the crystal substrate 1. In the present invention, since the adhesiveness between the crystal substrate and the insulating film is high, and stress relaxation such as normal transformation is observed at the interface between the insulating film and the second epitaxial layer, the film is easily peelable, and for example, the HF etching step is not essential and can be omitted.

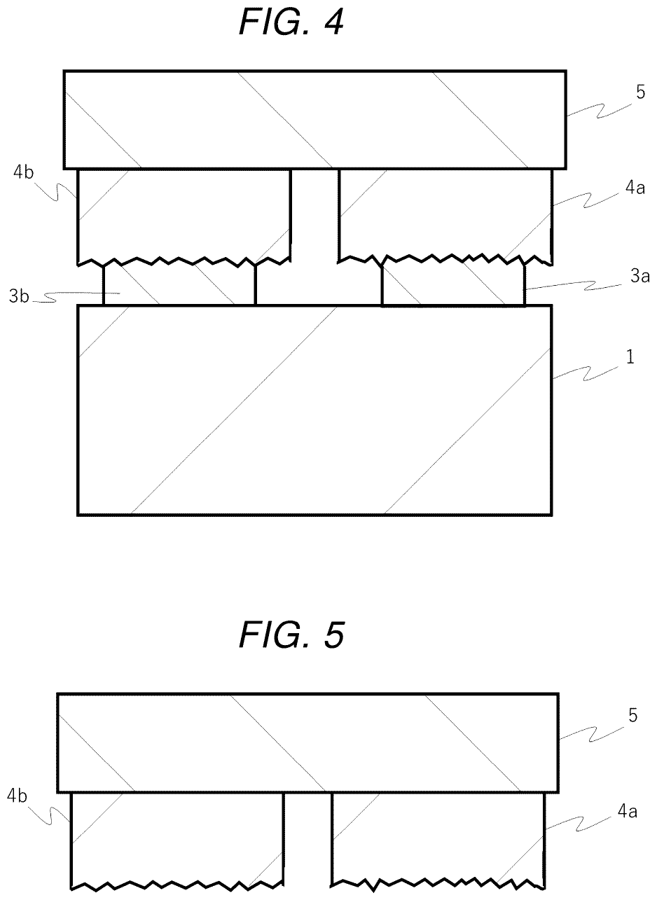

FIG. 4 illustrates a laminated structure obtained in an attaching step of attaching to a flexible substrate in the peeling and transfer. In the attaching step, the SOI layer surface and the flexible substrate 5 made of polyethylene (PE) are attached to each other closely using the laminated structure illustrated in FIG. 3.

FIG. 5 illustrates a laminated structure obtained in a peeling step of the peeling and transfer. In the peeling step, the SOI layer is peeled off and transferred to the flexible substrate. By doing so, it is possible to make the transfer success rate more excellent, increase the yield in device manufacturing, and achieve higher quality at lower cost.

### INDUSTRIAL APPLICABILITY

The crystal and the laminated structure according to the present invention are useful for an element, an electronic device, an electronic apparatus, and a system, and are particularly preferably used as an SOI substrate.

### REFERENCE SIGNS LIST

1 Crystal substrate
2 Oxide film
3 Insulating film (first epitaxial layer)
3a First pillar of first epitaxial layer
3b Second pillar of first epitaxial layer
4 Second epitaxial layer
4a First island of second epitaxial layer
4b Second island of second epitaxial layer
5 Flexible substrate
13 Insulating film
14 Conductive film
21 Gate electrode
22 Emitter electrode
23 Collector electrode
24 Drain electrode
25 Source electrode
26 Insulating film
26a Insulating film (epitaxial layer)
27 p-type semiconductor
28 n-type semiconductor
28a n-type semiconductor
29 Crystal substrate
30 Trench isolation
31 Polysilicon
101a to 101b Metal source
102a to 102j Earth
103a to 103b ICP electrode
104a to 104b Cut filter
105a to 105b DC power supply
106a to 106b RF power supply
107a to 107b Lamp
108 Ar source
109 Reactive gas source
110 Power supply
111 Substrate holder
112 Substrate
113 Cut filter
114 ICP ring
115 Vacuum chamber
116 Rotary shaft
1001 Crystal film
1002 First amorphous layer
1003 Second amorphous layer
1004 Buried layer
1011 Substrate

1. A crystal made of a crystalline metal compound containing a metal compound as a main component, wherein the metal compound includes compounds of Hf, Zr, and Si.

2. The crystal according to claim 1, wherein the crystalline metal compound has a cubic or hexagonal crystal structure.

3. The crystal according to claim 2, wherein the crystalline metal compound is oriented in a (111), (100), (010) or (0001) direction.

4. The crystal according to claim 1, wherein the crystalline metal compound contains 5 or more atomic percent of a compound of Si with respect to the crystalline metal compound.

5. The crystal according to claim 1, wherein the crystalline metal compound contains 50 or more atomic percent of both a compound of Hf and a compound of Zr with respect to the crystalline metal compound.

6. The crystal according to claim 1, being a ferroelectric.

7. The crystal according to claim 1, being in a form of a film.

8. The crystal according to claim 7, having a film thickness of 1 μm or more.

9. A laminated structure, having a crystal film laminated on a crystal substrate directly or with another layer interposed therebetween, wherein the crystal film is made of the crystal according to claim 1.

10. The laminated structure according to claim 9, wherein the crystal film constitutes a part or the whole of a buffer layer and is a substrate for crystal growth.

11. An element having a crystal, wherein the crystal is the crystal according to claim 1.

12. The element according to claim 11, being a piezoelectric element or a semiconductor element.

13. An electronic device having a crystal, wherein the crystal is the crystal according to claim 1.

14-18. (canceled)

19. The laminated structure according to claim 9, comprising: between the crystal substrate and the crystal film, an amorphous thin film that contains the constituent metals of the crystal film and/or the crystal substrate, and/or one or more buried layers that are embedded in a part of the crystal substrate and contain the constituent metals.

20. The laminated structure according to claim 19, comprising: between the crystal substrate and the crystal film, an amorphous thin film that contains the constituent metals of the crystal film, and/or one or more buried layers that are embedded in a part of the crystal substrate and contain the constituent metals of the crystal film.

21. The laminated structure according to claim 19, comprising: between the crystal substrate and the crystal film, an amorphous thin film that contains the constituent metals of the crystal film and/or the crystal substrate, and one or more buried layers that are embedded in a part of the crystal substrate and contain the constituent metals.

22. The laminated structure according to claim 19, wherein the constituent metal includes Hf.

23. The laminated structure according to claim 19, wherein the amorphous thin film has a film thickness of 1 nm to 10 nm inclusive.

24. The laminated structure according to claim 19, wherein the buried layer has an approximately inverted triangular cross-sectional shape.

25. An electronic device, an electronic apparatus, or a system having a laminated structure, wherein the laminated structure is the laminated structure according to claim 19.

26-27. (canceled)
